(19) United States
(12) Patent Application Publication
(10) Pub. No.: US 2011/0001505 A1
(43) Pub. Date: Jan. 6, 2011

(54) TEST SOCKETS FABRICATED BY MEMS TECHNOLOGY FOR TESTING OF SEMICONDUCTOR DEVICES

(76) Inventor: Jaewoo Nam, Gunpo-Si (KR)

Correspondence Address: Invent Capture, LLC, 3319 Foxtail Terrace, Fremont, CA, 94536, US

(21) Appl. No.: 12/829,873

(22) Filed: Jul. 2, 2010

(30) Foreign Application Priority Data
Jul. 2, 2009 (KR) 10-2009-0060113

(51) Int. Cl. G01R 31/02

(52) U.S. Cl. 324/756.02; 324/762.01; 324/763.01

(57) ABSTRACT

The present invention dicloses test sockets fabricated by MEMS technology for testing of semiconductor devices. Semiconductor device test sockets fabricated by MEMS technology in accordance with one or more embodiments of the invention offer many unique advantages over conventional test sockets (e.g. sockets utilizing pogo-pins). In one embodiment of the invention, a novel test socket includes a substrate with multiple cavities of certain depths in middle region of one side, electrical contacts (electrodes) of cantilever type directly above the cavities making individual contact with each contactor of semiconductor device, and multiple signal paths electrically connecting the cantilever type contacts on one side of the substrate and the loadboard PCB(printed circuit board) or motherboard PCB placed on the other side of the substrate.

### FOREIGN-PRIORITY CLAIM

This application claims foreign-priority to a Korean Intellectual Property Office utility patent application filed on Jul. 2, 2009. The application number of this foreign priority application is 10-2009-0060113.

### BACKGROUND OF THE INVENTION

### Field of the Invention

The present invention generally relates to test sockets for testing semiconductor devices. More specifically, the present invention relates to MEMS-based semiconductor test sockets for ensuring good electrical connection between a test hardware (e.g. automatic test equipment, or ATE) and semiconductor devices by forming physical and electrical contacts using MEMS technology.

Generally, an integrated circuit (IC) performs many operations and is typically designed with multiple I/O (input/output) signal paths to support them. An IC chip is frequently packaged into Ball Grid Array (BGA) type of enclosure, which has multiple electrical contactors in an array formation of rows and columns on the bottom side. These electrical contactors are in a ball shape to make electrical or mechanical contacts with a PCB.

An IC device goes through a series of electrical tests and burn-in tests for product qualification before an outgoing shipment. Test socket is necessary for in performing these tests. Electrical tests are performed by connecting every I/O contactor of a device to test signal-generating circuitries of test hardware. Tests are designed to verify the electrical characteristics of devices such as I/O performance, pulse characteristics, processing performance and conformance to noise tolerance limitation. The burn-in tests are similar to normal electrical tests but at higher operating temperature and higher supply voltage to simulate device aging in real-world applications.

Traditional test sockets have the following structure, as illustrated in FIG. 1. To make connection with external test circuit board, the solder balls underneath a device in BGA type package (10) need to make physical tensioned-contacts with pogo-type pins (40) on an external enclosure structure, under which a separate interface board for testing is positioned. A device inserter (20) with latch (21) is needed to internally position the BGA package (10) and apply downward pressure to securely hold the device package so that solder balls on the device can make contact with the pogo-pins.

Traditionally the BGA package is held in place by the device inserter (20) to make direct contact with pogo pins (40) on the bottom case (30). The contact force created by this contact can only be controlled by the elasticity of the pogo pins and this can result in contact failure. If the downward pressure from the BGA type device at inserter (20) is not evenly distributed by the latch (21) or if the tension of individual pogo pins (40) is not consistent, the quality of contact can degrade even further.

The pogo pins (40) or solder balls on the BGA package (10) can also be damaged by less than optimal contacts, caused by uneven contact direction or force between them.

For accurate testing of semiconductor devices, stable levels of electrical characteristics like contact resistance and impedance are necessary, but traditional test sockets with pogo type pins cannot guarantee these due to elasticity and quality of gold plating variances among individual pogo pins. Additionally, signal paths need be shorter in high frequency testing but fundamental shape and structure of pogo pins present physical and mechanical limitations in manufacturing and assembly processes. A certain minimum length of spring is required for stable contact pressure and contact stroke with solder balls. There is a limitation on reducing the length of spring while maintaining these characteristics in shorter pogo pins.

Keeping sufficient contact stroke for better contact requires longer pogo pins. Each pogo pin needs to handle about 20-27 g of spring tension to be able to maintain contact resistance of less than 0.5 ohm. This is becoming an issue as today's semiconductor devices in flip-chip, MCP (multi-chip package) and CSP (chip scale package) are thinner with larger number of solder ball or bump contacts. A device with just 1,000 contact solder balls would require 1,000×20 g=20 kg of overall contact pressure, enough to destroy the device packaging itself during testing.

Traditional test sockets utilizing pogo type contacts also have a serious limitation in reducing the pitch between pogo pins due to their structural layout of components. Manufacturing of traditional pogo-pin typed test sockets with lower pitch and higher density characteristics to meet current generation of semiconductor devices' ever increasing contact density in smaller form factor is a real challenge. To accommodate BGA type semiconductor device package with 600-1,000 solder ball contacts, pogo type-based test sockets require more complex pogo pins and enclosures, resulting in complicated manufacturing process and higher cost. In testing applications, a defective pogo pin requires a replacement of that pin but the process is difficult and time-consuming. The cost, in terms of equipment and labor, is very high.

### SUMMARY

Summary and Abstract summarize some aspects of the present invention. Simplifications or omissions may have been made to avoid obscuring the purpose of the Summary or the Abstract. These simplifications or omissions are not intended to limit the scope of the present invention.

In one embodiment of the invention, a test socket with cantilever type of contacts, which is fabricated utilizing semiconductor device manufacturing process and MEMS (Micro Electro Mechanical Systems) technology, addresses the current issues with traditional test sockets with pogo-pin type contacts.

The advantages of the invention are as follows:

Shape, length, width, thickness and structure of cantilever contacts are easily controllable in manufacturing process, resulting in reduced pitch between electrical contacts. In addition, contact force is minimized while contact resistance with solder ball on the device is maintained at low levels. This helps prevent damage to the device package. Furthermore, wide range of applications, e.g. burn-in test and high frequency test, are made possible with this invention, regardless of semiconductor device types or package types. Moreover, manufacturing of test sockets is greatly simplified due to integration into a single unit, no need for assembly of pogo pins to the enclosure, smaller form factor and by using an automated batch process. In addition, test sockets, which have low pitch, high density, high frequency, lower contact pressure, more compact, and higher performance, are made possible by the invention.

The first characteristics of this invention includes the following:

A substrate with multiple cavities of certain depths in middle region of one side.

The electrical contacts (electrodes) of cantilever type directly above the cavities making individual contact with each contactor of semiconductor device.

Multiple signal paths electrically connecting the cantilever type contacts on one side of the substrate and the loadboard PCB (printed circuit board) or motherboard PCB placed on the other side of the substrate.

A conductive bump on top side of cantilever is desirable to facilitate better contact, physically and electrically, with contactor of semiconductor device. This bump may be of one or more of gold, silver, molybdenum (MO), Beryllium, Copper, Titanium, Osmium, Paliney-7, Rhodium, Nickel or Aluminum.

The shape of conductive bump may be of a cylinder, a cone, a pyramid or a crown. The substrate, which is of silicone material, could have cavities filled with elastic material for better tension.

In addition, the above substrate and portion of cantilever is of non-conductive material. Other portion of cantilever is of conductive metal and a buffer layer may be formed on the bottom side of the substrate.

The portion of the above cantilever may have one or more layers of silicone, epitaxial silicone, silicon dioxide (SiO2) or silicon nitride (Si3N4) of certain thickness. The shape of cantilever may be of a rectangle, a square, a circle or an oval. The underside of cantilever may be downward stepper-shaped as in (e) of FIG. 10.

The second characteristics of this invention includes the following:

A multi-layered motherboard or loadboard PCB with multiple cavities of certain depths on upper side.

The electrical contacts (electrodes) of cantilever type directly above the cavities making individual contact with each contactor of semiconductor device.

Multiple signal paths electrically connecting the cantilever type contacts to the motherboard or loadboard multi-layer PCB(printed circuit board).

A cantilever is formed from multilayered PCB and may be of one or more of silicone, ceramic, plastic, synthetic resins or conductive metal. The conductive bump on top side of cantilever is desirable to facilitate better contact, physically and electrically, with contactors of semiconductor device. The cavities may be filled with elastic material for better tension and a buffer layer may formed on the bottom side of the PCB.

The third characteristics of this invention includes the following:

A multi-layered motherboard or loadboard PCB with tension layers of elastic material on the top side.

Conductive metal contacts (electrodes) of cantilever type above the tension layer, making contact with contactors of semiconductor devices

Vertical conductive metal connectors through the tension layer down to the multi-layered motherboard or loadboard PCB.

It is desirable to integrate the cantilever and vertical conductive metal connector into a single structure.

The benefits of the invention are as follows:

Cantilever of the test socket based on this invention features a planary matrix layout which can be precisely controlled in terms of various structures, shapes, thicknesses, widths and lengths at manufacturing. These test sockets can have greatly reduced pitch between electrical contacts, resulting in smaller form factor with higher density of electrical contact area.

The contact pitch between solder balls on the semiconductor device can be reduced, resulting in smaller semiconductor devices with lower manufacturing cost. The end appliances using these smaller semiconductor devices will be slimmer and of higher performance. The overall cost will be lower, making it more economical.

Cantilever with planary matrix layout can be precisely controlled in terms of various structures, shapes, thicknesses, widths, lengths and tension properties at manufacturing. The contact resistance at the solder balls of semiconductor devices can be maintained at a lower level while contact force exerted on the solder balls is minimized. This can prevent damages to the semiconductor devices. Manufacturing is simpler as well-known semiconductor IC fabrication process is used and there is no need for assembly of individual components. As an integrated unit without any needs for assembly, defective unit can be easily replaced minimizing loss of time, equipment and labor.

This invention is suitable to a wide range of test applications—e.g. burn-in test and high frequency test—regardless of semiconductor device types. This invention enables test sockets that are inherently easy to customize, standardize, repeatability, mass production with higher contact density. It can also help reduce cost of high performance sockets with fine pitch, high density, high frequency, low contact force in smaller form factor.

This invention can also eliminate the high cost of traditional test sockets by bonding or embedding the multilayered PCB with cantilevers in planary matrix layout, directly onto the multilayered PCB of motherboard or loadboard. This invention offers the benefits of drastically improving various electrical properties such as impedance and inductance. It greatly lowers the cost of semiconductor devices testing by simplifying the overall test hardware requirements.

This invention enables manufacturing of smaller test sockets with high density of electrical contacts, which in turn makes it possible to reduce the size of semiconductor devices for lower overall cost of production. Semiconductor devices in smaller packages can make it possible to produce various end products with slimmer form factor, improved performance and lower cost. This invention can also prevent damages to the semiconductor devices as it maintains low contact resistance between ball contacts of semiconductor devices and electrical contacts on test sockets while minimizing the contact force on ball contacts of semiconductor devices.

The invention can be used to test many diverse types of semiconductor devices in various packages, e.g. the burn-in test applications and high frequency test applications. And as the socket is integrated into a single unit without requiring an assembly process, this invention has many advantages of lower manufacturing cost, customizable contacts to requirements, better integration into a smaller unit, higher yield/throughput, finer pitch between contacts, automated batch manufacturing and etc.

### BRIEF DESCRIPTION OF DRAWINGS

FIG. 1 shows a configuration of traditional test socket of pogo-pin type.

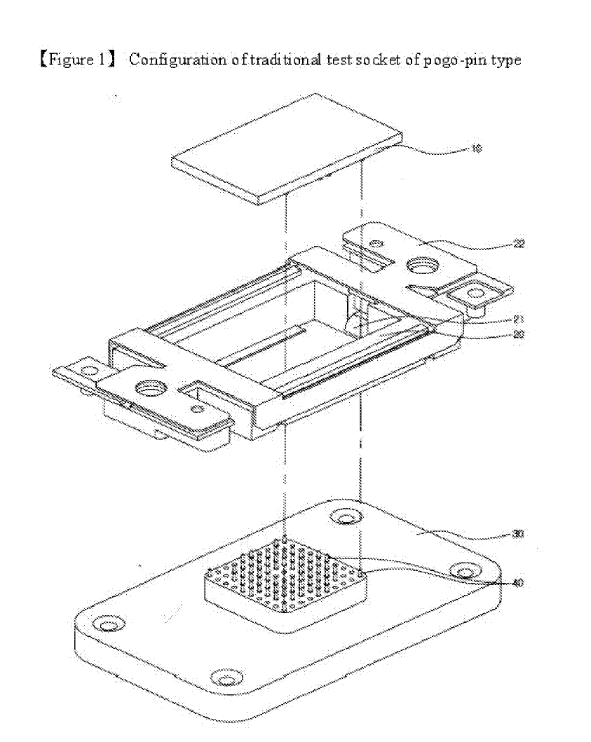

FIG. 2 shows a cross-sectional view of test environment based on this invention.

FIG. 3 shows fabrication processes of test socket based on this invention.

FIG. 4 shows an example of fabrication processes of test socket based on this invention.

FIG. 5 shows another example of fabrication processes of test socket based on this invention.

FIG. 6 shows a cross-sectional view of semiconductor device test socket based on this invention.

FIG. 7 shows a perspective view of a semiconductor device test socket based on this invention

FIG. 8 shows various shapes of bumps on cantilevers based on this invention

FIG. 9 shows various shapes of cantilever types of test socket, based on this invention.

FIG. 10 shows an example of test socket with multilayered PCB, based on this invention.

FIG. 11 shows a cross-sectional view of another test socket with conductive metal and PCB, based on this invention.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

The detailed description is presented largely in terms of description of shapes, configurations, and/or other symbolic representations that directly or indirectly resemble test sockets fabricated by MEMS technology for testing of semiconductor devices. These process descriptions and representations are the means used by those experienced or skilled in the art to most effectively convey the substance of their work to others skilled in the art.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment. Furthermore, separate or alternative embodiments are not necessarily mutually exclusive of other embodiments. Moreover, the order of blocks in process flowcharts or diagrams representing one or more embodiments of the invention do not inherently indicate any particular order nor imply any limitations in the invention.

### Example 1

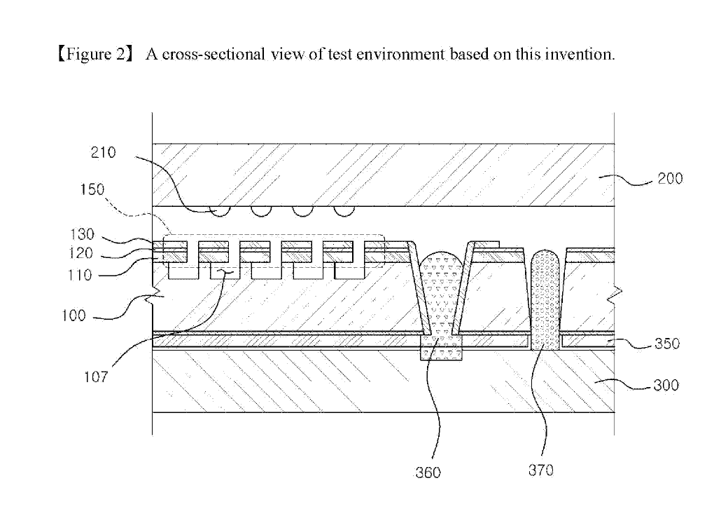

FIG. 2 illustrates the cross-sectional view of a typical test setup with semiconductor device, test socket based on this invention and motherboard or loadboard PCB. This test setup is comprised of the following.

Motherboard or loadboard PCB (300) that is used to interface with test equipment to test semiconductor devices.

A substrate (100) with multiple cavities of certain depth in the middle region, which is placed on top side of motherboard or loadboard.

Cantilever type electrodes (150) that are directly above the cavities (107) to make individual contacts with contactors of semiconductor device.

It is desirable to form cantilever with layers of silicon dioxide (SiO2) or silicon nitride (Si3N4) (120) over silicon base layer (110). Single-crystal silicon generally has a crystalline orientation yet is stronger than stainless steel and no deformation occurs up to the breaking point. Silicon is highly brittle, less hysteretic and highly durable up to breakdown point.

Silicon also has a high tension property and easily recovers from deformation caused by external forces. Its gauge factor is much greater than metal strain gauge. Silicon has many uses for MEMS applications.

Layers of silicon (110), epitaxial silicon (110), silicon dioxide (SiO2) or silicon nitride (Si3N4) (120) on silicon base substrate (100), which has excellent elasticity and durability, can be used as cantilever that can elastically induce mechanical contacts with solder balls (210) of semiconductor devices.

Cantilevers (150) could be composed of insulating material like ceramic, engineering plastic, glass, synthetic resins, acrylic resin reinforced, reinforced polyester, reinforced polymer or conductive metal. Bottom side of substrate could be a buffer layer of materials like urethane polymer, polyimide, epoxy, teflon or silicon rubber.

The electrodes on cantilever can be any of silicon, ceramic, plastic, synthetic resins or conductive metal materials that have elastic properties. Using these materials simplify the manufacturing and machining processes, resulting in lower cost.

As the silicon, used as substrate (100) on a test socket, is of the same material as the semiconductor device, all physical properties are identical. This ensures superior connectivity between test socket and semiconductor device under testing in a wide range of testing applications. Use of identical material also facilitates better integration with superior signal-to-noise ratio.

The fact that well-known semiconductor fabrication process is used to implement this invention means manufacturing is simpler and can be automated for higher productivity with lower cost. This invention can also promote total automation of test process while simplifying it and resulting in drastically lowered cost of test.

Traditional pogo-pin type test sockets rely on pogo pins with spring to make contact with a semiconductor device. This method has limitations in reducing pitch and is difficult to manufacture. Electrical contacts (electrodes) of a test socket by this invention are fabricated on a single planary matrix layout without further assembly or components, while a traditional socket needs be assembled with individual pogo pins. The proposed test socket also functions as interposer, physically and electrically connecting the semiconductor device (200) and motherboard/loadboard PCB (300). The vertically movable cantilever type electrodes (150) in planary matrix layout directly over the cavities on the substrate can produce stability with strong elasticity, better material properties, higher density and higher efficiency test sockets.

The individual cantilevers (150) are independent of each other, thus evenly distribute contact force over electrodes, resulting in more consistent contacts and more accurate testing.

The cavity with certain depth could be vacant space or be filled with elastic material. Use of elastic material could also help evenly distribute the contact force over each cantilever for better contacts.

For this elastic material, urethane polymer, polyimide, epoxy, teflon, phenol, polyester, silicon rubber or other synthetic rubber/resin are well suited as they offer high insulation, high elasticity, high restitution, low thermal expansion coefficient, Low Heat Shrinkage and high melting point. Various metal springs—coil spring, leaf spring, gap spring—coated with insulating materials are also well suited.

The substrate (100) could be of non-conductive materials like ceramic, engineering plastics, synthetic resin, glass, reinforced acryl resin, reinforced polyester or reinforced polymer. Metal with insulated coating may also be used as substrate. The bottom side of the substrate (100) may be a buffer layer composed of synthetic rubber like urethane, polymer, polyimide, epoxy, teflon, silicon rubber or resin.

The cantilever (150) can contain at least one layer of silicon, epitaxial silicon, silicon dioxide (SiO2) or silicon nitride (Si3N4). The cantilever may be of ceramic, plastic, synthetic resin or conductive metal that has elasticity and may assume a shape and structure of rectangle, square, circle, ellipse, oval, ball ring, T or stepper. The cantilever can have various thicknesses, widths, lengths from um-mm and desired properties of elasticity and performance can be achieved by varying combination of them.

As in FIG. 2, a semiconductor device (200) in BGA type package has solder balls on connections to the circuitry. Connections to external test system from the solder balls are required to test the performance and circuit integrity of the semiconductor device. Testing is performed by making physical contacts between electrodes of the test socket and solder balls of the device.

As the semiconductor devices achieve higher density, pitch between signal paths get smaller and the pitch between solder balls which make electrical contacts get smaller. This poses issues of less accuracy and reliability in device testing not to mention the difficulty of setting up the test environment.

This invention addresses these issues by implementing cantilevers with vertical deflection, in planary matrix layout, over cavities instead of using sockets of pogo types.

Tradition methods need elastic component like spring to provide elasticity but have a limitation on reducing the pitch between pogo pins. This invention, using test socket of cantilevers in planar matrix layout, can considerably reduce the pitch between electrodes by controlling the shape, structure, thickness, width and length of cantilever and its electrode.

The total length of cantilever is between 100 um to 500 um. It can be used to test any device, e.g., high frequency/high speed devices, regardless of package type. As it uses well-known semiconductor IC fabrication process and MEMS technology, it is feasible to obtain very small form factor, standardization, customization, mass production, high repeatability and high density at low cost.

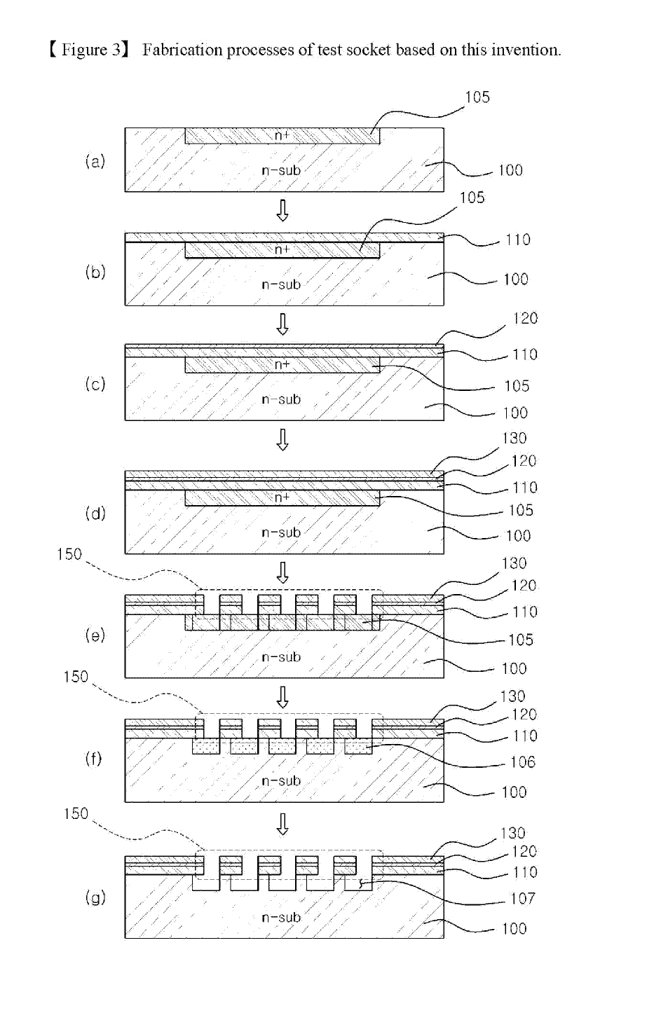

FIG. 3 illustrates the fabrication process of semiconductor device test socket based on this invention.

(a) A diffusion layer (105) of 20-50 um deep is formed on n+ type silicon layer to make desired cavities in the middle region of n type silicon substrate (100). (FIG. 3(a))

(b) A layer of epitaxial silicon (110), with thickness of up to 100 um, is grown on top of silicon substrate (100) and n+ diffusion layer (105). (FIG. 3(b))

(c) Silicon dioxide (SiO2) or silicon nitride (Si3N4) layer (120) is deposited as an insulation layer on top of epitaxial silicon layer (110). (FIG. 3(c))

Designed signal paths (130) are formed to be connected to external test system and electrodes. (FIG. 3(d))

The Silicon dioxide (SiO2) or silicon nitride (Si3N4) layer is coated with photoresist (PR) and matrix shaped mask pattern is formed via photolithography. Using wet or dry etching, silicon dioxide (SiO2) or silicon nitride (Si3N4) layer is removed to expose multiple N+ diffusion layer (105). The resultant is the cantilever (150) in matrix layout on top of N+ diffusion layer. (FIG. 3(e))

The silicon wafer is dipped in high density HF solution. A few minutes of anodization changes the n+ diffusion layer into porous silicon layer (106) (PSL process). (FIG. 3(f))

(g) Finally, the porous silicon layer (106) is etched in 5% NaOH or other etching solution. The cantilevers (150) are formed that can have up/down deflection over the cavity (107). (FIG. 3(g))

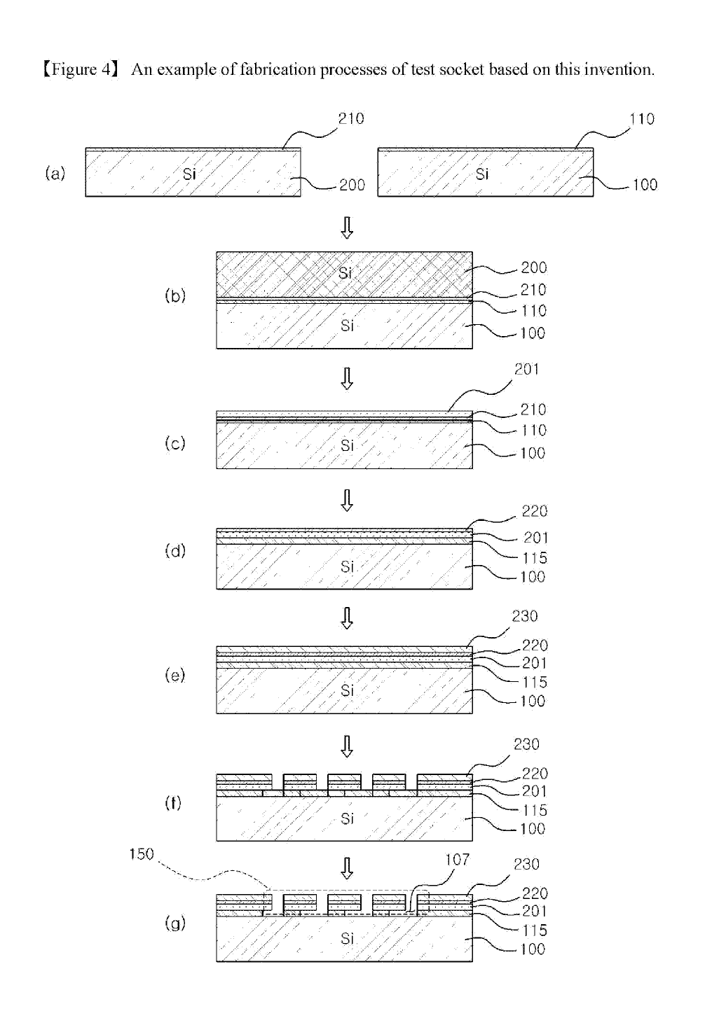

FIG. 4 illustrates another example of the fabrication process of semiconductor device test socket based on this invention.

A layer of silicon dioxide (SiO2) is deposited on each of two silicon substrates (100,200), as in FIG. 4. (FIG. 4(a))

Two substrates (100,200) are bonded on the sides of silicon dioxide (SiO2) layer via Silicon Direct Bonding (SDB) process. (FIG. 4(b))

Upper silicon substrate is polished down to form a silicon layer (201) with a specific thickness via lapping process. (CMP—chemical mechanical polishing) (FIG. 4(c))

A layer of silicon dioxide (SiO2) or silicon nitride (Si3N4) is deposited on the surface of silicon layer (201) polished down via chemical mechanical polishing (CMP) process. (FIG. 4(d))

Electrical signal paths (230) are formed by photolithographic process and metal deposition is applied. These signal paths are laterally connected to the top of cantilever according to the layout. The materials with high conductivity are suitable for electrical signal paths and they include gold, silver, platinum, copper, tungsten, nickel and aluminum. (FIG. 4(e)).

The electrical contact parts of cantilever type are formed by applying photolithographic etching process, using matrix patterned mask, to top of silicon layer (201), silicon dioxide (SiO2) layer or silicon nitride (Si3N4) layer (220). The buried layer (115) of silicon dioxide (SiO2) is etched by dry or wet etching process to fabricate a test socket with multiple cantilever type electrodes as based on this invention. (FIG. 4(g))

When bonding the top and bottom substrates via silicon direct bonding (SDB) process, forming SOG (silicon on glass) film instead of silicon dioxide (SiO2) layer may be beneficial because forming a layer of silicon dioxide (SiO2) layer with a specific thickness requires expensive equipment like plasma enhanced chemical vapor deposition (PECVD).

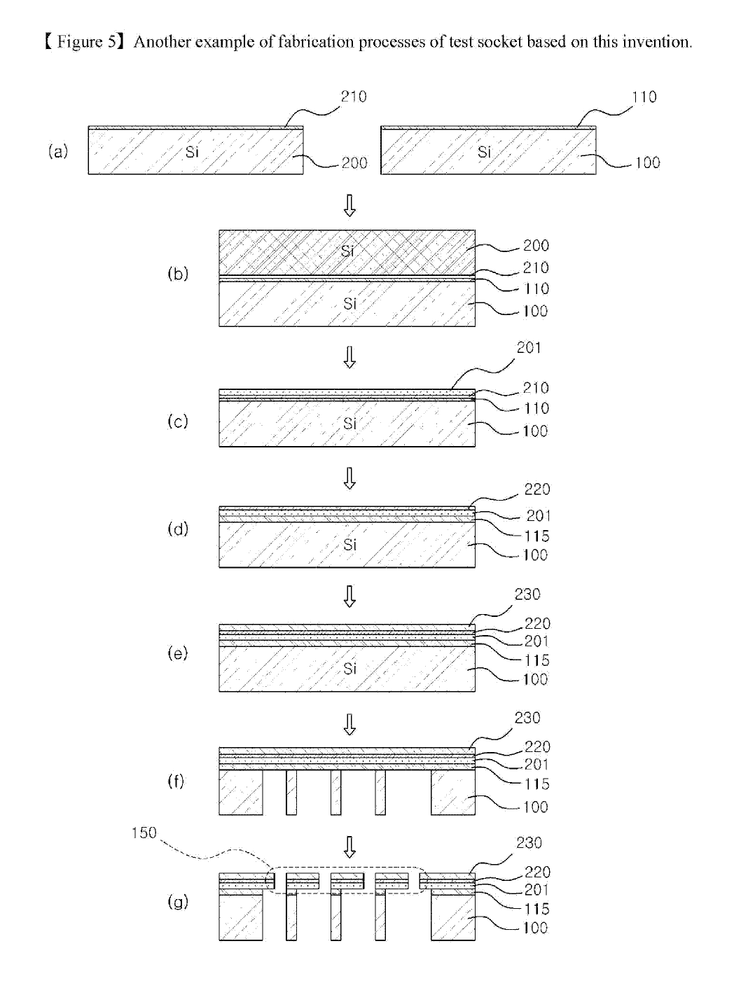

The FIG. 5 illustrates yet another example of fabrication process for semiconductor device test socket based on this invention.

Note that steps (a) and (e) of FIG. 5 are identical to steps (a) and (e) of FIG. 4 respectively, thus duplicate description is omitted.

To obtain the cavity to allow for the vertical deflection of the cantilever, DRIE (Deep Reactive Ion Etching) can be used on the bottom side (100) of cantilever (150) instead of wet-etching silicon dioxide (SiO2) layer or silicon substrate to a specific depth. Cantilevers to contact with semiconductor devices can be formed by using a matrix patterned mask via photolithographic process, to etch away top layer (220) of silicon (201), silicon dioxide (SiO2) or silicon nitride (Si3N4).

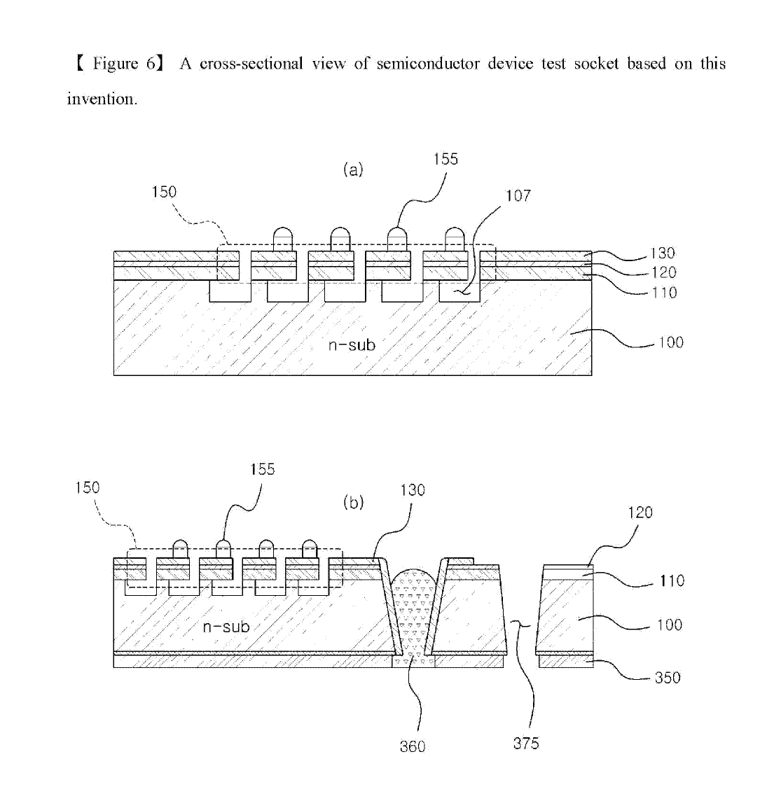

FIG. 6 illustrates an example structure of a semiconductor device test socket based on this invention. As in FIG. 6(a), a layer of silicon, epitaxial silicon (110), silicon dioxide (SiO2) or silicon nitride (Si3N4) (120) and a layer of signal paths (130) are deposited to form multiple layers on the silicon substrate (100). Then a number of cavities of specific depth are formed on the middle region of the substrate (100) to create a number of cantilever type electrodes directly above them. The conductive bumps (155) are formed at tips of electrodes (150), which are connected to the signal paths. These bumps facilitate better contacts with contactors on the semiconductor devices.

Unlike the example of FIG. 3, the invention illustrated by FIG. 6(a) features conductive bumps (155) at the end of signal paths on the cantilever to aide in better contacts with semiconductor device. With better contact, higher test efficiency is obtained.

It is beneficial to form conductive bumps on top part of cantilevers (150) to aide in better electrical and physical contacts with solder balls or leads on the semiconductor device. The suitable materials for the conductive bumps (155) include hard metals like molybdenum (MO), tungsten, Beryllium-Copper alloy, titanium, osmium, paliney-7, rhodium, nickel alloy, platinum, gold alloy and silver alloy for their excellent conductive properties. Metal plated hard metal like gold is also very suitable for its conductivity and resistance to oxidation.

The FIG. 6 illustrates the cross-sectional view of semiconductor test socket's overall configuration. A number of through-holes penetrating the substrate are formed, connecting the signal paths on top to the motherboard or loadboard PCB on the bottom side of the substrate, serving as the paths for electrical signals. Furthermore, through-holes are formed on the outer area of the substrate as guide holes (375). Guide holes facilitates for reliability and reproducibility of test sockets by securely and accurately connecting the substrate to the motherboard or loadboard PCB and hold in place with screws or pins through the holes.

It is also advisable to have a buffer layer between the substrate and motherboard or loadboard PCB to prevent damage to the substrate or to PCB by damping the vertical pressure caused by frequent contacts between electrodes of semiconductor device and the electrical contacts of the substrate.

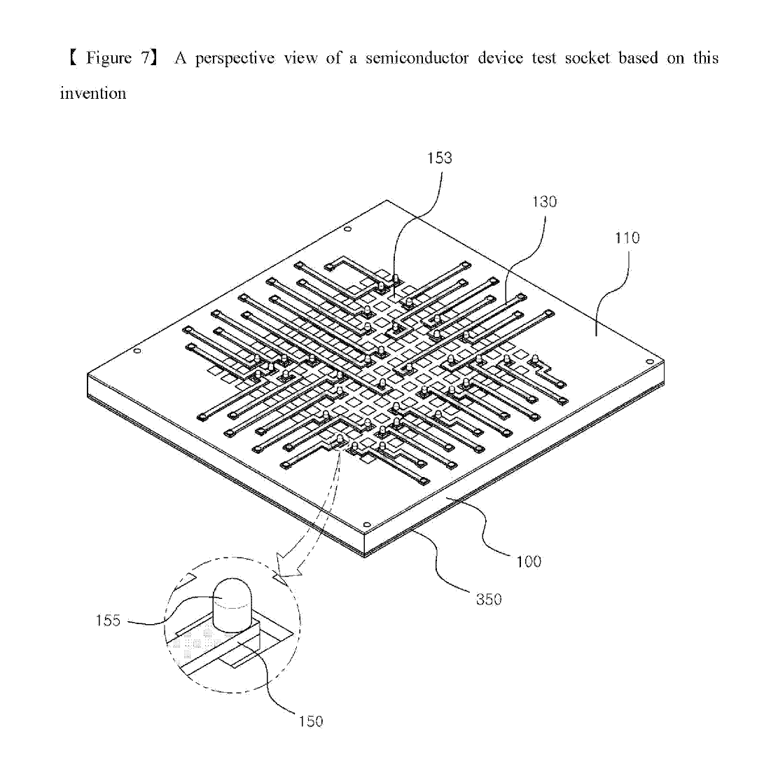

FIG. 7 illustrates the overall configuration of semiconductor device test socket based on this invention. A number of separate cavities (153) that allows for vertical movements of cantilevers are formed in the central area of the substrate. Cantilever type electrodes are formed over select cavities and electrical signal paths to motherboard or loadboard PCB, which is situated under the substrate, are extended from the electrodes (150).

The layout of signal paths (130) and electrodes (150) are fully configurable to accommodate the circuit layout or package type of the semiconductor device. The signal paths (130) may be connected to the motherboard or loadboard PCB on the bottom side of the substrate through the holes in the outer area of the substrate.

As illustrated in FIG. 7, guide holes are drilled at periphery of the substrate, providing secure connections to the motherboard or loadboard PCB under the substrate. Between the substrate (100) and the motherboard or loadboard PCB is a buffer layer (350) which absorbs and dampens the downward pressure from numerous contacts at testing.

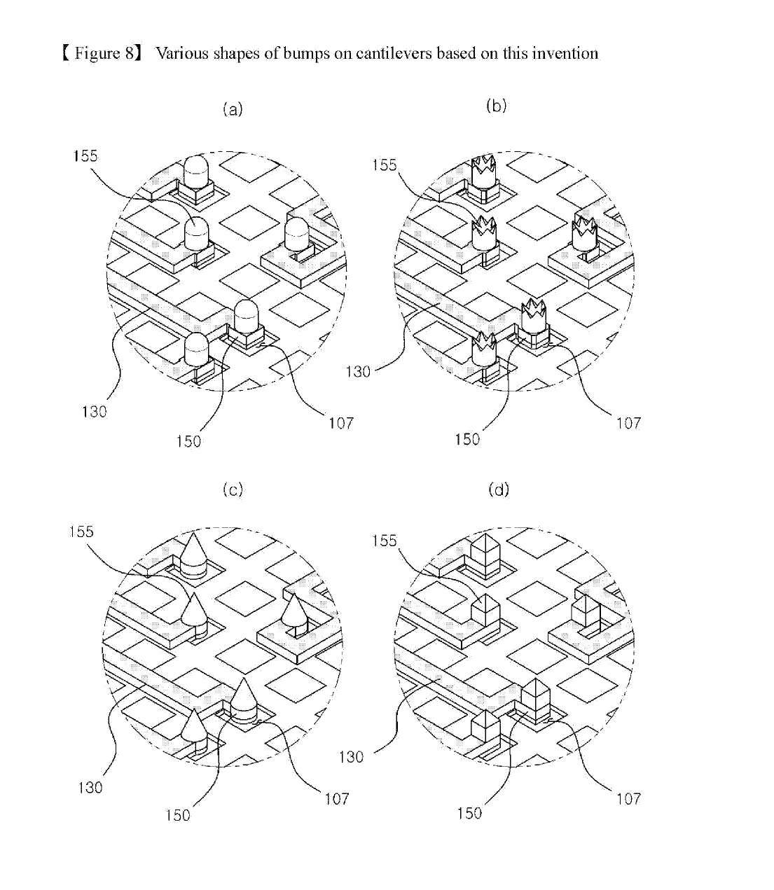

FIG. 8 illustrates the various types and shapes of cantilever type electrodes (150), signal paths (130) and conductive bumps (155) of semiconductor device test socket based on this invention. The electrical contact surface makes frequent contacts with semiconductor device's solder balls and may be of planary type. The tip of conductive bump could be of various shapes like a cylinder with dome head, a crown, a cone or a pyramid. These bumps enables more stable contacts with solder balls. Having a micro structured tip on a bump is highly beneficial in testing semiconductor device.

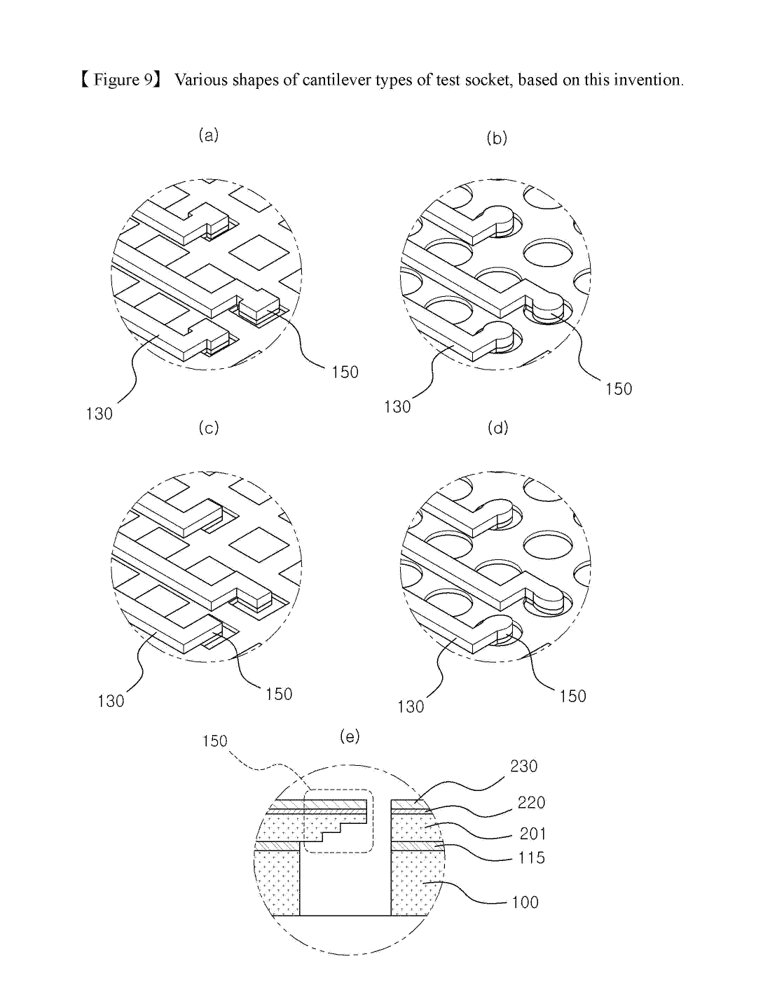

FIG. 9 illustrates various shapes and configurations of cantilever type electrical contact parts of semiconductor device test sockets based on this invention. The electrical contacts of cantilever may be square (a), circular (b), rectangular (c) or oval (d) shape. The choice of shape for cantilever may depend on layout of electrical paths and suitability for custom contact requirements. Shapes other than ones illustrated in FIG. 9 could be manufactured as needed.

The FIG. 9(e) illustrates a cross-sectional view of a cantilever based on this invention. The thickness of stepper-shaped cantilever on upper part of the substrate is getting thinner toward the end. This is to maintain good vertically elastic property against up and down movements from numerous contacts with semiconductor device's contactors. It is also feasible to adopt from a variety of other structures and layouts, depending on electrical and physical requirements.

### Example 2

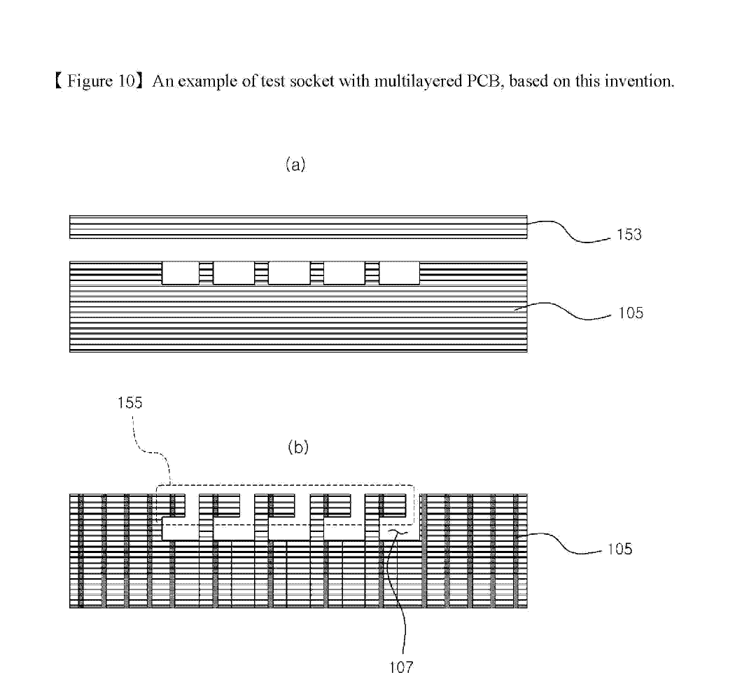

FIG. 10 illustrates another of implementation of semiconductor device test socket based on this invention. Unlike previous implementations, a multilayered PCB (105) is used in place of substrate as is the cantilever type electrical contact parts (155). Cavities (107) with certain depth are formed on the motherboard or loadboard PCB and they (107) are filled with elastic material. A printed circuit board (PCB) with specific thickness is then bonded over the cavities. The cavities can also be left vacant if needed.

As illustrated by (b) of FIG. 10, cantilever type electrical contact parts (155) could be formed by micro-machined holes on the PCB that is bonded over the cavities. The PCB panel is generally of hard materials like ceramic, teflon, epoxy resin, polyimide film, phenol resin (FR-1,2,3,4,5), glass cloth resin (CEM-1), glass paper resin (CEM-3) or polyester (PET), for their relatively high elasticity. They also act as insulating material where there is no electrical traces. The use of multilayered PCB has an advantage of easy connectivity of signals.

This implementation, shown in FIG. 10, connects signal cantilever (155) on the base PCB to the motherboard or loadboard PCB without separate signal paths. This is due to the fact that a multilayered PCB inherently contains signal connections and traces on each layer. A vertical through-hole or via-hole filled with conductive material, as needed, will form electrically connected loop-circuits.

That is, when vertical through-holes (105) are drilled at specific locations on the upper surface of multilayered PCB and connected to the motherboard or loadboard PCB, cantilever becomes a part of loop-circuits. The lower side of the multilayered PCB (105) may have a buffer layer to dampen the downward pressure exerted by repeated contacts at cantilevers on top side of the PCB panel.

In the example implementation as in the FIG. 10, the PCB base has inherent elasticity to make cantilevers deflect. It also has an advantage of simpler connections via through-holes.

### Example 3

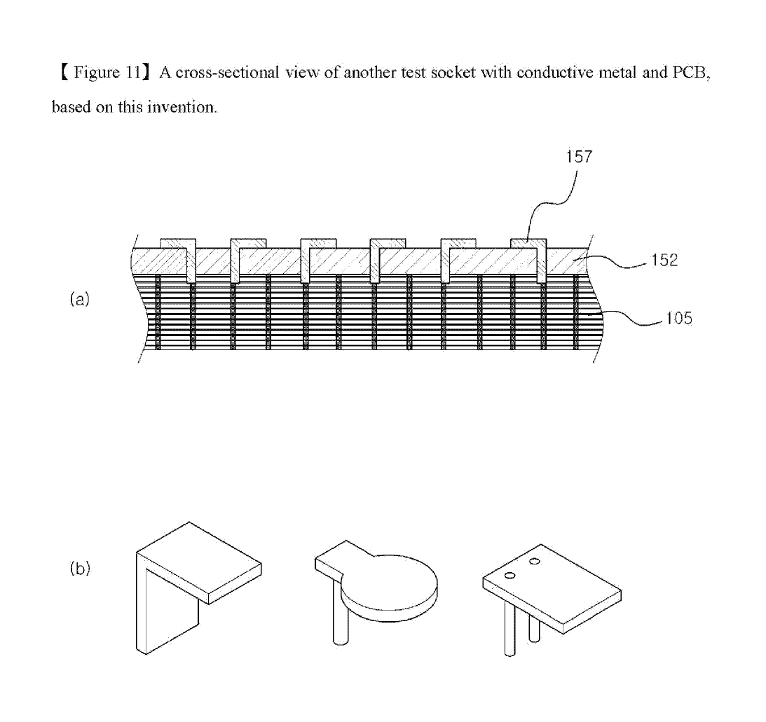

FIG. 11 illustrates another implementation of semiconductor device test socket, also based on this invention. This implementation of test socket is comprised of motherboard or loadboard multilayer PCB base (105), a elastic layer of elastic material above the PCB base, cantilever of conductive metal material that makes direct contacts with electrodes of semiconductor device and cantilever (157), electrically connecting to the multilayer PCB base.

That is, an elastic layers of suitable material with specific thickness is formed on the top side of multilayered PCB (105) and “L” shaped electrical contact parts (157) are inserted on the top side in planary matrix layout. The cantilever (157) are made of conductive material. They are comprised of cantilevers making individual contacts with electrodes of semiconductor device and vertical signal paths through elastic layer, down to the multilayer PCB base, making electrical connections.

The example implementation of test socket in FIG. 11 is easy to manufacture. Its cantilever (157) are individually inserted into the elastic layer, making consistent contacts with electrodes of semiconductor device. It's simple structure also makes manufacturing simple and individual failed cantilever could easily be replaced. The FIG. 11(b) illustrates various possible shapes of cantilever (157) but additional shapes are also feasible to enhance the performance and efficiency of the test socket. Additionally, the cantilever and vertical connection at cantilever (157) could be integrated into a single structure or separate components as needed. Conductive bumps may be formed on the tips of electrical contact parts (157)

As demonstrated, this invention can drastically reduce the thickness of the test socket and pitch between the electrodes. This invention is well suited for high frequency signal processing and a diverse range of semiconductor devices regardless of types. Use of integrated circuit (IC) fabrication process and micro-machining in manufacturing can also promote standardization, automated mass production, customization, integration and repeatability with lower overall cost. This invention also has a wide range of uses in interposer/connection applications where electrical signals connections between micro systems and macro systems are needed.

Several examples of this invention are described with figures and descriptions. It should be clear to anyone with knowledge of the technology and industry that diverse customizations/variations are still possible within the claims of this invention.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. Semiconductor device test sockets fabricated with MEMS technology, featuring the following characteristics:
1) A substrate with multiple cavities of certain depths in middle region of one side;
2) The electrical contacts (electrodes) of cantilever type directly above the cavities making individual contact with each contactor of semiconductor device; and
3) Multiple signal paths electrically connecting the cantilever type contacts on one side of the substrate and the load board PCB (printed circuit board) or mother board PCB placed on the other side of the substrate.

2. Semiconductor device test sockets fabricated with MEMS technology of claim 1, featuring a conductive bumps, on tip of cantilevers, to facilitate physical or electrical contacts with electrodes on semiconductor device.

3. Semiconductor device test sockets fabricated with MEMS technology of claim 1, featuring cavities filled with elastic material.

4. Semiconductor device test sockets fabricated with MEMS technology of claim 1, featuring a substrate of silicon material.

5. Semiconductor device test sockets fabricated with MEMS technology of claim 1, featuring parts of base substrate or cantilever are of insulating material.

6. Semiconductor device test sockets fabricated with MEMS technology of claim 1, featuring a buffer layer under base substrate.

7. Semiconductor device test sockets fabricated with MEMS technology of claim 1, featuring cantilever with a stepper shape.

8. Semiconductor device test sockets fabricated with MEMS technology, featuring the following characteristics:
1) A multi-layered motherboard or loadboard PCB with multiple cavities of certain depths on upper side;
2) The electrical contacts (electrodes) of cantilever type directly above the cavities making individual contact with each contactor of semiconductor device; and
3) Multiple signal paths electrically connecting the cantilever type contacts to the motherboard or loadboard multi-layer PCB (printed circuit board).

9. Semiconductor device test sockets fabricated with MEMS technology of claim 8, featuring cantilevers composed of PCB panel.

10. Semiconductor device test sockets fabricated with MEMS technology of claim 8, featuring cantilever composed of at least one material of silicon, ceramic, plastic, synthetic resin or conductive metal.

11. Semiconductor device test sockets fabricated with MEMS technology of claim 8, featuring cavities at base PCB panel filled with elastic material.

12. Semiconductor device test sockets fabricated with MEMS technology of claim 8, featuring a buffer layer under the PCB base.

13. Semiconductor device test sockets fabricated with MEMS technology, featuring the following characteristics:
1) A multi-layered motherboard or loadboard PCB;
2) A tension layers of elastic material on the top side;
3) Conductive metal contacts (electrodes) of cantilever type above the tension layer, making contact with contactors of semiconductor devices; and
4) Vertical conductive metal connectors through the tension layer down to the multi-layered motherboard or loadboard PCB.

14. Semiconductor device test sockets fabricated with MEMS technology of claim 13, featuring integrated cantilever and vertical conductive metal connector.
